(19) United States
(12) Patent Application Publication
(10) Pub. No.: US 2007/0155135 A1
(43) Pub. Date: Jul. 5, 2007

(54) METHOD OF FABRICATING A POLYSILICON LAYER AND A THIN FILM TRANSISTOR

(76) Inventors: Yun-Pei Yang, Changhua County (TW); Te-Hua Teng, Taoyuan County (TW); Chih-Jen Shih, Changhua County (TW); Chia-Chien Lu, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,899

(22) Filed: Jan. 16, 2006

(30) Foreign Application Priority Data
Jan. 5, 2006 (TW) 95100430

(51) Int. Cl. H01L 21/20; H01L 21/36

(52) U.S. Cl. 438/478

(57) ABSTRACT

A method of fabricating a polysilicon layer is provided. A substrate having a front surface and a back surface is provided. A buffer layer, an amorphous layer and a cap layer are sequentially formed on the front surface of the substrate. The cap layer is patterned to form a patterned cap layer exposing a portion of the amorphous layer, wherein the exposed portion of the amorphous layer is a crystallization initial region. A metallic catalytic layer is formed on the patterned cap layer, wherein the metallic catalytic layer contacts with the crystallization initial region of the amorphous layer. A laser annealing process is performed through the back surface of the substrate so that the amorphous layer is crystallized and transformed into a polysilicon layer from the crystallization initial region.

### CROSS-REFERENCE TO RELATED APPLICATION

This application claims the priority benefit of Taiwan application serial no. 95100430, filed on Jan. 5, 2006. All disclosure of the Taiwan application is incorporated herein by reference.

### BACKGROUND OF THE INVENTION

1. Field of the Invention

The present invention generally relates to a method of fabricating a polysilicon layer and a thin film transistor. More particularly, the present invention relates to a method of fabricating a polysilicon layer and a thin film transistor using a back laser heating process.

2. Description of Related Art

Displays are communication interface for people and information. Currently, flat display panels comprises organic electro-luminescence display (OELD), plasma display panel (PDP), liquid crystal display (LCD) and light emitting diode (LED).

For the displays as above mentioned, thin film transistors are usually used as driving devices. Classified based on material of channel regions, thin film transistors include amorphous silicon (a-Si) thin film transistors and polysilicon thin film transistors. With the electron mobility of the polysilicon thin film transistor can be larger than 200 cm²/V-sec and the polysilicon thin film transistor occupies smaller area that can satisfy high aperture ratio requirement for improving brightness and reducing power consuming, the polysilicon thin film transistor has got more attention than the a—Si thin film transistor in the industry. In addition, since the polysilicon thin film transistor has high electron mobility, it can be used as a part of driving circuits so that the display panel manufacturing cost can be reduced.

In the fabricating process of the polysilicon thin film transistor, one method for forming the polysilicon layer is a metal induced lateral crystallization with a furnace thermal process. In this method, an amorphous layer and a metallic catalytic will react at 500˜600° C. to perform solid phase crystallization so that the amorphous layer is transformed into a polysilicon layer. However, the method needs long time (more than ten hours) thermal annealing. The problems of glass deforming and metallic catalytic remaining may occur.

Alternatively, the polysilicon layer can be formed by a excimer laser annealing. The excimer laser having high energy may melt the amorphous layer, and then the amorphous layer will re-crystallize when cooling. Thus, the amorphous layer can be transformed into a polysilicon layer. But, this method has disadvantages including high power consuming, smaller grain size, more defects in the polysilicon layer, poor uniformity and narrow process window.

In addition, the polysilicon layer can also be formed by a pulse rapid thermal annealing with a metal induced lateral crystallization. In this method, an amorphous layer contacts with a metallic catalytic and a pulse rapid thermal annealing is performed for providing thermal energy for the amorphous layer. Although the method just need several minutes, it is difficult to apply to large-size display panel manufacturing because the instruments are not easy to large-scaled.

### SUMMARY OF THE INVENTION

Accordingly, the present invention is directed to a method of fabricating a polysilicon layer capable of reducing laser annealing time and laser annealing power consuming and having good film quality.

The present invention is directed to a method of fabricating a thin film transistor using the method for forming the polysilicon layer as above mentioned so as to fabricate a thin film transistor in which the polysilicon layer has good quality.

A method of fabricating a polysilicon layer is provided. A substrate having a front surface and a back surface is provided. A buffer layer, an amorphous layer and a cap layer are sequentially formed on the front surface of the substrate. The cap layer is patterned to form a patterned cap layer exposing a portion of the amorphous layer, wherein the exposed portion of the amorphous layer is a crystallization initial region. A metallic catalytic layer is formed on the patterned cap layer, wherein the metallic catalytic layer contacts with the amorphous layer in the crystallization initial region. A laser annealing process is performed through the back surface of the substrate so that the amorphous layer is crystallized and transformed into a polysilicon layer from the crystallization initial region.

According to an embodiment of the present invention, the laser annealing process is an excimer laser annealing process.

According to an embodiment of the present invention, the wavelength of the excimer laser annealing process is 308 nm.

According to an embodiment of the present invention, the step of forming the metallic catalytic layer on the patterned cap layer comprises performing one of an evaporation process, a sputter process, a chemical vapour deposition process, a physical vapour deposition process or and coating process.

According to an embodiment of the present invention, the metallic catalytic layer comprises ferrum (Fe), cobalt (Co), palladium (Pd), nickel (Ni), gold (Au), antimony (Sb), platinum (Pt), titanium (Ti), zinc (Zn), silver (Ag) and a combination thereof.

According to an embodiment of the present invention, the step of sequentially forming the buffer layer, the amorphous layer and the cap layer on the front surface of the substrate comprises performing a chemical vapour deposition process.

According to an embodiment of the present invention, the buffer layer comprises one of silicon oxide and silicon nitride.

According to an embodiment of the present invention, the cap layer comprises silicon oxide.

According to an embodiment of the present invention, the substrate comprises one of glass and quartz.

According to an embodiment of the present invention, the method further comprising removing the patterned cap layer and the metallic catalytic layer after the laser annealing process is performed.

A method of fabricating a thin film transistor is also provided. A substrate having a front surface and a back surface is provided. A buffer layer, an amorphous layer and a cap layer are sequentially formed on the front surface of the substrate. The cap layer is patterned to form a patterned cap layer exposing a portion of the amorphous layer, wherein the exposed portion of the amorphous layer is a crystallization initial region. A metallic catalytic layer is formed on the patterned cap layer, wherein the metallic catalytic layer contacts with the amorphous layer in the crystallization initial region. A laser annealing process is performed through the back surface of the substrate so that the amorphous layer is crystallized and transformed into a polysilicon layer from the crystallization initial region. After patterned cap layer and the metallic catalytic layer are removed, the polysilicon layer in the crystallization initial region is removed, such that a plurality of polysilicon islands are formed. Thereafter, a gate insulating layer is formed to cover the polysilicon islands. A plurality of gates are formed on the gate insulating layer. A source and a drain are formed in each of the polysilicon island beside the gate, and a channel region is formed between the source and the drain.

According to an embodiment of the present invention, the laser annealing process is an excimer laser annealing process.

According to an embodiment of the present invention, the wavelength of the excimer laser annealing process is 308 nm.

According to an embodiment of the present invention, the step of forming the metallic catalytic layer on the patterned cap layer comprises performing one of an evaporation process, a sputter process, a chemical vapour deposition process, a physical vapour deposition process and a coating process.

According to an embodiment of the present invention, the metallic catalytic layer comprises ferrum (Fe), cobalt (Co), palladium (Pd), nickel (Ni), gold (Au), antimony (Sb), platinum (Pt), titanium (Ti), zinc (Zn), silver (Ag) and a combination thereof.

According to an embodiment of the present invention, the step of sequentially forming the buffer layer, the amorphous layer and the cap layer on the front surface of the substrate comprises performing a chemical vapour deposition process.

According to an embodiment of the present invention, the buffer layer comprises one of silicon oxide and silicon nitride.

According to an embodiment of the present invention, the cap layer comprises silicon oxide.

According to an embodiment of the present invention, the substrate comprises one of glass and quartz.

According to an embodiment of the present invention, the method further comprises forming a passivation layer to cover the polysilicon islands and the gates; patterning the passivation layer to expose the sources and the drains; and forming a source metal layer and a drain metal layer on the passivation layer, wherein the source metal layer and the drain metal layer are electrically connected to the exposed sources and drains.

In the present invention, the polysilicon layer is formed by a laser annealing process through the back surface of the substrate with a metal induced lateral crystallization. Thus, the crystallization efficiency can be improved. Besides, since melting the amorphous layer is not required and the laser annealing is used for providing thermal energy for performing the metal induced lateral crystallization, the present invention has advantages of less annealing time, low power consuming and low diffusing effect of the metallic catalytic.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A˜FIG. 1E are cross-sectional views showing a method of forming a polysilicon layer according to an embodiment of the present invention.

FIG. 2A˜FIG. 2E are cross-sectional views showing a method of forming a thin film transistor according to an embodiment of the present invention.

FIG. 3A˜FIG. 3C are cross-sectional views showing a method of forming a passivation layer and a source and drain metal layer over the thin film transistor according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

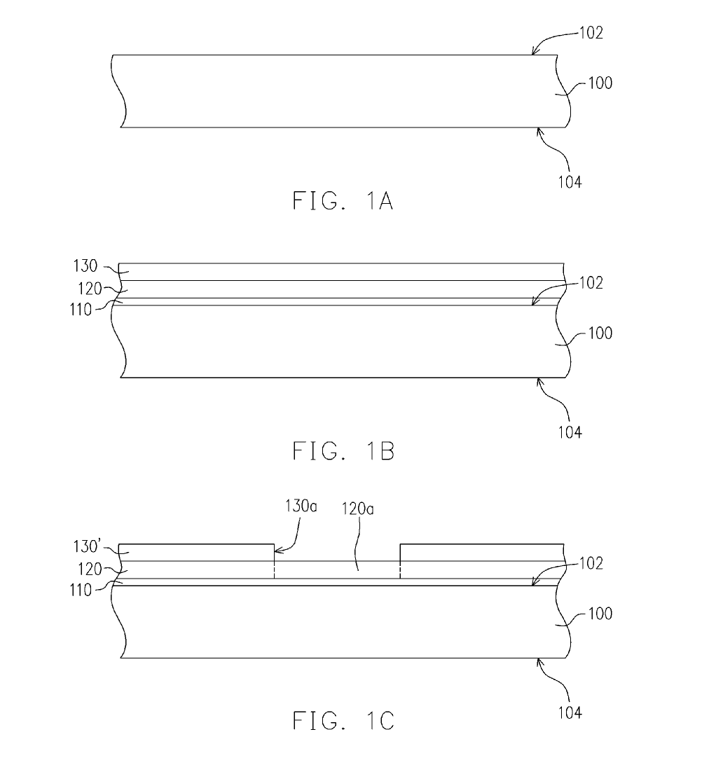

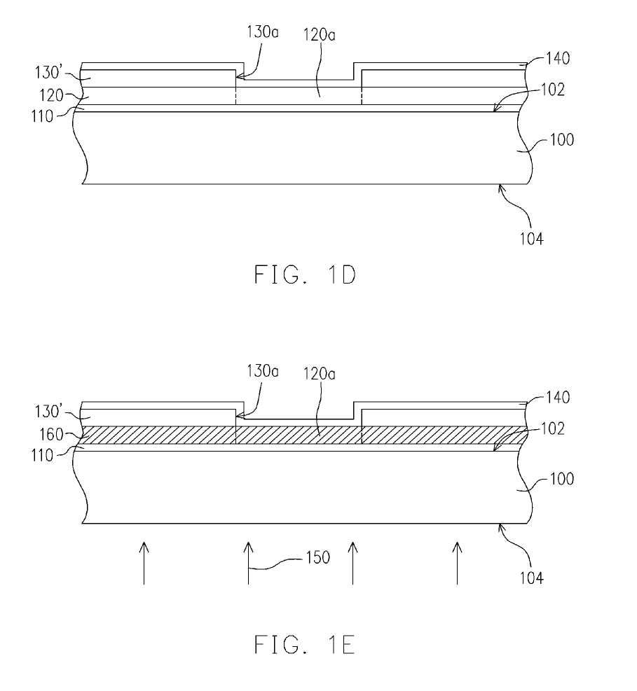

FIG. 1A˜FIG. 1E are cross-sectional views showing a method of forming a polysilicon layer according to an embodiment of the present invention. As shown in FIG. 1A, a substrate 100 having a front surface 102 and a back surface 104 is provided. In an embodiment, the substrate 100 is a transparent substrate, such as a glass substrate or a quartz substrate.

Next, as shown in FIG. 1B, a buffer layer 110, an amorphous layer 120 and a cap layer 130 are sequentially formed on the front surface 102 of the substrate 100. In an embodiment, the method for forming the buffer layer 110, the amorphous layer 120 and the cap layer 130 on the front surface 102 of the substrate 100 comprises performing a chemical vapour deposition process. The material of the buffer layer 110 comprises silicon oxide or silicon nitride, for example. The buffer layer 110 can improve the adhesion between the amorphous layer 120 and the substrate 100 and block impurities in the substrate 100 diffusing into the amorphous layer 120. The material of the cap layer 130 comprises silicon oxide, for example. The cap layer 130 will be patterned to be a mask for defining a crystallization initial region 120a (shown in FIG. 1C) subsequently.

Thereafter, as shown in FIGS. 1B and 1C, the cap layer 130 is patterned to form a patterned cap layer 130′ exposing a portion of the amorphous layer 120. The exposed portion of the amorphous layer 120 is a crystallization initial region 120a. In an embodiment, the method for patterning the cap layer is a photolithography and etching process. The patterned cap layer 130′ has an opening 130a that exposes the crystallization initial region 120a of the amorphous layer 120.

Next, as shown in FIG. 1D, a metallic catalytic layer 140 is formed on the patterned cap layer 130′, and the metallic catalytic layer 140 contacts with the amorphous layer 120 in the crystallization initial region 120a. The method for forming the metallic catalytic layer 140 on the patterned cap layer 130′ may comprise an evaporation process, a sputter process, a chemical vapour deposition process, a physical vapour deposition process or a coating process, for example. The material for the metallic catalytic layer 140 comprises, for example, ferrum (Fe), cobalt (Co), palladium (Pd), nickel (Ni), gold (Au), antimony (Sb), platinum (Pt), titanium (Ti), zinc (Zn), silver (Ag) and a combination thereof.

Please refer to FIG. 1E, a laser annealing process 150 is performed through the back surface 104 of the substrate 100 so that the amorphous layer 120 in crystallization initial region 120a (shown in FIG. 1D) is crystallized and transformed into a polysilicon layer 160. In an embodiment, the laser annealing process 150 is an excimer laser annealing process. Preferably, the wavelength of the excimer laser annealing process is 308 nm because the amorphous layer 120 can efficiently absorb the laser energy at wavelength of 308 nm.

The detailed step of forming the polysilicon layer 160 from the amorphous layer 120 is described as follows. Please refer to FIG. 1D and FIG. 1E, the amorphous layer 120 may absorb the laser energy so that the whole amorphous layer 120 is heated. In the meanwhile, because the amorphous layer 120 in the crystallization initial region 120a contacts with the metallic catalytic layer 140, the metallic catalytic layer 140 at this region may first react with the amorphous layer 120 to form a metal silicide (not shown). Moreover, since the metal silicide has a crystal lattice similar to polysilicon, it can serve as a seed. Thus, a metal induced lateral crystallization (MILC) is carried out starting at the crystallization initial region 120a of the amorphous layer 120. And then, the amorphous layer 120 is transformed into a polysilicon layer 160.

It should be noted that the laser annealing process 150 does not melt the amorphous layer 120. The laser annealing process 150 is used for providing thermal energy for the amorphous layer 120 during the metal induced lateral crystallization. Therefore, the method for forming the polysilicon layer in the present invention has advantages of low power consuming and high crystallization efficiency. In addition, the annealing process used in the present invention is a laser annealing so that the annealing time can be reduced and the fabricating efficiency of the polysilicon layer is improved. Furthermore, since the annealing time is reduced, the diffusing effect of the metallic catalytic can be reduced so as to avoid remaining the metallic catalytic residue.

In particular, the laser annealing process 150 performed through the back surface 104 of the substrate 100 has an advantage of that the laser is not reflected by the metallic catalytic layer 140 on the front surface 102 of the substrate 100. As a result, the laser energy consuming can be reduced and the heating efficiency of the laser annealing process 150 can be improved.

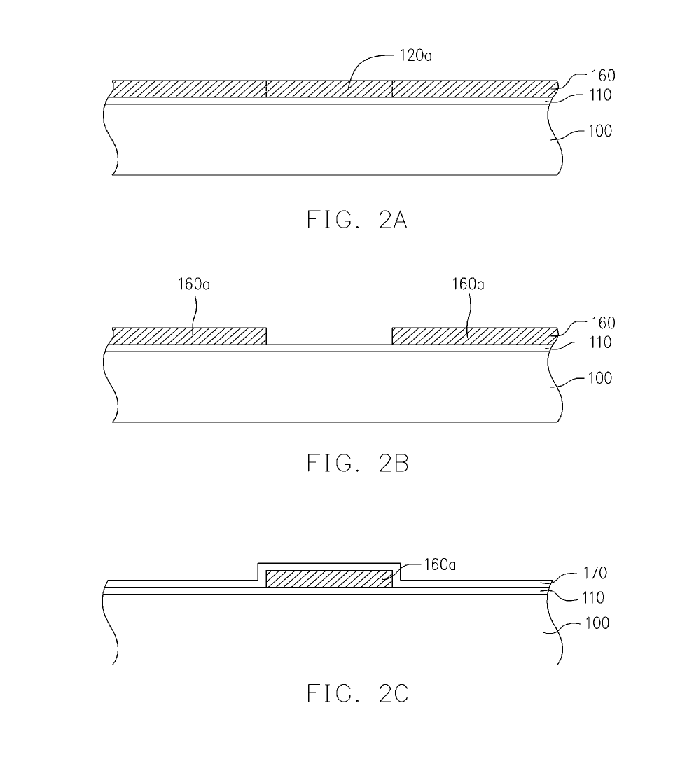

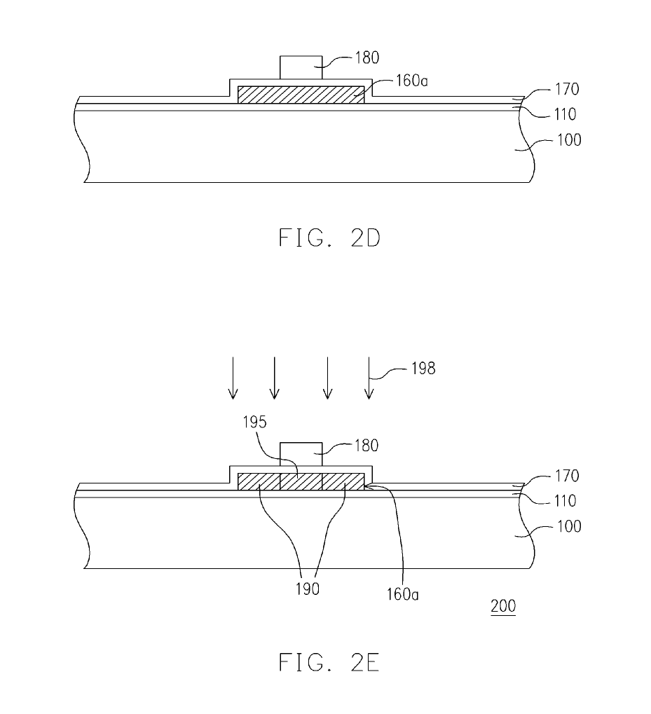

According to another embodiment of the present invention, after performing the laser annealing process 150 of FIG. 1E, the patterned cap layer 130′ and the metallic catalytic layer 140 are further removed to expose the polysilicon layer 160 (as shown in FIG. 2A) so as to be processed subsequently.

For the foregoing, comparing with the conventional methods, the method of fabricating a polysilicon layer of the present invention has advantages of less annealing time, low diffusing effect of metallic catalytic, high crystallization efficiency and low power consuming. Besides, because the instruments or equipments for forming the polysilicon layer can be large-scaled easily, the method of the present invention is suitable for applying to fabricate polysilicon thin film transistors of a large-size liquid crystal display. The method for forming a thin film transistor having the polysilicon layer fabricated by the above mentioned method is described as follows.

FIG. 2A˜FIG. 2E are cross-sectional views showing a method of forming a thin film transistor according to an embodiment of the present invention. As shown in FIG. 2A, a substrate 100 having a polysilicon layer 160 thereon is provided. A buffer layer 110 is formed between the polysilicon layer 160 and the substrate 100. The polysilicon layer 160 is fabricated by the method shown in FIG. 1A˜FIG. 1E. In particular, the crystallization initial region 120a has high concentration metallic catalytic therein.

As shown in FIG. 2A and FIG. 2B, the polysilicon layer 160 at the crystallization initial region 120a is removed and the remained polysilicon layer 160 is a polysilicon island 160a. Because the crystallization initial region 120a has high concentration metallic catalytic therein, it is not suitable for being used as a channel of a thin film transistor. The method of removing the polysilicon layer 160 at the crystallization initial region 120a is a photolithography and etching process, for example.

Thereafter, as shown in FIG. 2C, a gate insulating layer 170 to cover the polysilicon island 160a. FIG. 2C shows one of the polysilicon islands 160a for illustration. The method for forming the gate insulating layer 170 is a chemical vapor deposition process, for example. The material for the gate insulating layer 170 comprises silicon oxide or silicon nitride, for example.

Please refer to FIG. 2D, a gate 180 is formed on the gate insulating layer 170. In an embodiment, the gate 180 is formed by the steps of depositing a gate metal layer (not shown) and then performing a photolithography and etching process. Alternatively, the gate 180 can be formed by performing a depositing process with a shadow mask to deposit a gate 180 on the gate insulating layer 170.

As shown in FIG. 2E, a source/drain 190 is formed in the polysilicon island 160a beside the gate 180, and a channel 195 is formed between the source and the drain 190. The source/drain 190 is formed by performing an implantation process using the gate 180 as a mask so as to implant ions into the polysilicon island 160a. Thus, a thin film transistor 200 having a source/drain 190, and channel 195 and a gate 180 is formed.

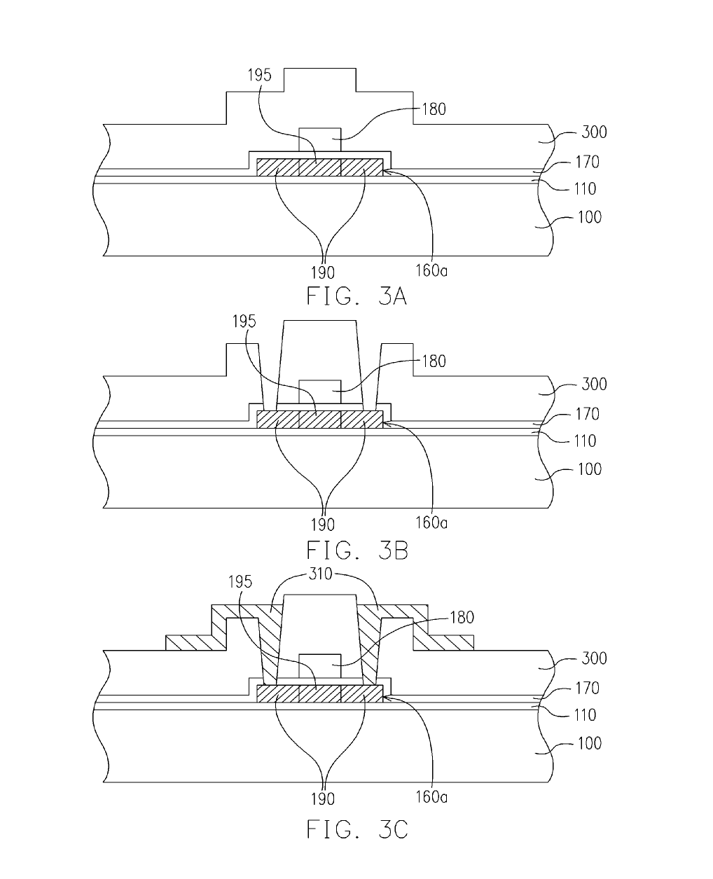

According to an embodiment, the method of forming a thin film transistor further comprises the steps shown in FIG. 3A˜FIG. 3C. First, as shown in FIG. 3A, a passivation layer 300 is formed to cover the polysilicon islands 160a and the gate 180. The passivation layer 300 can be formed by a chemical vapor deposition process or a plasma enhanced chemical vapor deposition process. The material of the passivation layer 300 comprises silicon oxide or silicon nitride. Thereafter, as shown in FIG. 3B, the passivation layer 300 is patterned to expose the source/drain 190. The patterning process is a photolithography and etching process, for example. Then, as shown in FIG. 3C, a source/drain metal layer 310 is formed on the passivation layer 300, and the source/drain metal layer 310 is electrically connected with the source/drain 190.

For the foregoing, the method of fabricating a polysilicon layer and a thin film transistor includes advantages as follows:

1. The polysilicon layer is formed by a laser annealing process through the back surface of the substrate with a metal induced lateral crystallization. Because melting the amorphous layer is not required and the laser annealing is used for providing thermal energy for the amorphous to perform the metal induced lateral crystallization, the power consuming and the annealing time are reduced, and the crystallization efficiency can be improved.

2. Since the annealing time is reduced, the diffusing effect of the metallic catalytic can be reduced so as to avoid remaining the metallic catalytic residue.

3. Because the instruments or equipments for forming the polysilicon layer of the present invention can be large-scaled easily, the method is suitable for applying to fabricate polysilicon thin film transistors of a large-size liquid crystal display.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a polysilicon layer, comprising:
providing a substrate having a front surface and a back surface;
sequentially forming a buffer layer, an amorphous layer and a cap layer on the front surface of the substrate;
patterning the cap layer to form a patterned cap layer exposing a portion of the amorphous layer, wherein the exposed portion of the amorphous layer is a crystallization initial region;
forming a metallic catalytic layer on the patterned cap layer, wherein the metallic catalytic layer contacts with the amorphous layer in the crystallization initial region; and
performing a laser annealing process through the back surface of the substrate so that the amorphous layer is crystallized and transformed into a polysilicon layer from the crystallization initial region.

2. The method according to claim 1, wherein the laser annealing process is an excimer laser annealing process.

3. The method according to claim 2, wherein the wavelength of the excimer laser annealing process is 308 nm.

4. The method according to claim 1, wherein forming the metallic catalytic layer on the patterned cap layer comprises performing one of an evaporation process, a sputter process, a chemical vapour deposition process, a physical vapour deposition process and a coating process.

5. The method according to claim 1, wherein the metallic catalytic layer comprises ferrum (Fe), cobalt (Co), palladium (Pd), nickel (Ni), gold (Au), antimony (Sb), platinum (Pt), titanium (Ti), zinc (Zn), silver (Ag) and a combination thereof.

6. The method according to claim 1, wherein sequentially forming the buffer layer, the amorphous layer and the cap layer on the front surface of the substrate comprises performing a chemical vapour deposition process.

7. The method according to claim 1, wherein the buffer layer comprises one of silicon oxide and silicon nitride.

8. The method according to claim 1, wherein the cap layer comprises silicon oxide.

9. The method according to claim 1, wherein the substrate comprises one of glass and quartz.

10. The method according to claim 1, further comprising removing the patterned cap layer and the metallic catalytic layer after the laser annealing process is performed.

11. A method of fabricating a thin film transistor, comprising:
providing a substrate having a front surface and a back surface;
sequentially forming a buffer layer, an amorphous layer and a cap layer on the front surface of the substrate;
patterning the cap layer to form a patterned cap layer exposing a portion of the amorphous layer, wherein the exposed portion of the amorphous layer is a crystallization initial region;
forming a metallic catalytic layer on the patterned cap layer, wherein the metallic catalytic layer contacts with the amorphous layer in the crystallization initial region;
performing a laser annealing process through the back surface of the substrate so that the amorphous layer is crystallized and transformed into a polysilicon layer from the crystallization initial region;
removing the patterned cap layer and the metallic catalytic layer;
removing the polysilicon layer in the crystallization initial region, such that a plurality of polysilicon islands are formed;
forming a gate insulating layer to cover the polysilicon islands;
forming a plurality of gates on the gate insulating layer; and
forming a source and a drain in each of the polysilicon islands beside the gate, and a channel region is formed between the source and the drain.

12. The method according to claim 11, wherein the laser annealing process is an excimer laser annealing process.

13. The method according to claim 12, wherein the wavelength of the excimer laser annealing process is 308 nm.

14. The method according to claim 11, wherein forming the metallic catalytic layer on the patterned cap layer comprises performing one of an evaporation process, a sputter process, a chemical vapour deposition process, a physical vapour deposition process and a coating process.

15. The method according to claim 11, wherein the metallic catalytic layer comprises ferrum (Fe), cobalt (Co), palladium (Pd), nickel (Ni), gold (Au), antimony (Sb), platinum (Pt), titanium (Ti), zinc (Zn), silver (Ag) and a combination thereof.

16. The method according to claim 11, wherein sequentially forming the buffer layer, the amorphous layer and the cap layer on the front surface of the substrate comprises performing a chemical vapour deposition process.

17. The method according to claim 11, wherein the buffer layer comprises one of silicon oxide and silicon nitride.

18. The method according to claim 11, wherein the cap layer comprises silicon oxide.

19. The method according to claim 11, wherein the substrate comprises one of glass and quartz.

20. The method according to claim 11, further comprising:
forming a passivation layer to cover the polysilicon islands and the gates;
patterning the passivation layer to expose the sources and the drains; and
forming a source metal layer and a drain metal layer on the passivation layer, wherein the source metal layer and the drain metal layer are electrically connected to the exposed sources and drains.
